(19) United States
(12) Patent Application Publication
(10) Pub. No.: US 2019/0132938 A1
(43) Pub. Date: May 2, 2019

(54) FLOATING CORE HEAT SINK ASSEMBLY

(71) Applicant: HEATSCAPE.COM, INC., Morgan Hill, CA (US)

(72) Inventors: Ali Mira, Morgan Hill, CA (US); Yashar Mira, Morgan Hill, CA (US); Michael Mira, Morgan Hill, CA (US)

(21) Appl. No.: 15/986,755

(22) Filed: May 22, 2018

Related U.S. Application Data
(63) Continuation of application No. 15/900,565, filed on Feb. 20, 2018.
(60) Provisional application No. 62/579,624, filed on Oct. 31, 2017.

(51) Int. Cl. H05K 1/02

(52) U.S. Cl. CPC H05K 1/0203; H05K 2201/066; H05K 2201/10409

(57) ABSTRACT

Disclosed is a modular, floating core heatsink assembly used to transfer heat away from electronic components, such as computer chips. In particular, the floating core heatsink assembly may include a frame that can be fastened to a circuit board. The frame may have one or more apertures positioned over components of the circuit board. The assembly may also include one or more floating core heatsinks, which are configured to be dropped into the one or more apertures in the frame. The floating core heatsinks dissipate heat from the components of the circuit board without being thermally coupled to the frame.

### CROSS-REFERENCES TO RELATED APPLICATIONS

The present application is a continuation of U.S. application Ser. No. 15/900,565, filed Feb. 20, 2018, which claims the benefit and priority under 35 U.S.C. 119(e) of U.S. Provisional Application No. 62/579,624 filed Oct. 31, 2017, entitled FLOATING CORE HEAT SINK ASSEMBLY, the entire contents of which are incorporated herein by reference for all purposes.

### FIELD OF THE INVENTION

The present invention relates to heatsinks, and in particular, to a modular, floating core heat sink assembly that includes a frame and one or more floating core heat sinks that can be dropped into apertures in the frame.

### BACKGROUND OF THE INVENTION

Modern electronics are built with heat-generating electronic components mounted on circuit boards. Examples of these components include chips (e.g., microchips or integrated circuits) which draw a current for operation and can generate heat when used. For instance, processors such as central processing units (CPUs) and graphics processing units (GPUs) can generate a tremendous amount of heat as a result of performing numerous, extremely high-speed operations required for executing computer programs. That heat needs to be dissipated from the chip in order to allow the chip to operate efficiently. The chip may also be damaged if the heat is not dissipated and the temperature increases above a maximum threshold level. The computer industry is continually innovating cooling systems to address the unique and demanding cooling requirements of chips that produce large amounts of heat.

Heatsinks have been typically used to cool these chips. The heatsink is used to transfer heat away from the chip and towards cooling fins on the heatsink, which provides a large surface area for airflow to efficiently remove the heat from the heatsink through convection, conduction, and radiation (although to a lesser extent). A typical heatsink may be formed from a metal, such as copper or aluminum, which has a high thermal conductivity. In some cases, heatsinks may be used with vapor chambers to improve cooling by taking advantage of the high effective thermal conductivity of vapor chambers. A vapor chamber is a sealed vessel containing fluid that vaporizes in the vicinity of the hot component. The vapor migrates to a cooler surface of the vapor chamber, where it condenses and returns to the vicinity of the hot component. This vaporization and condensation cycle improves heat transfer from the hot component to the heatsink. The high thermal performance of vapor chambers can be combined with the cooling fins of traditional heatsinks by having a vapor chamber dissipate heat from the electric component (e.g., computer chips capable of generating tremendous amounts of heat) by transferring heat away from the electronic component and towards the cooling fins on a heatsink.

Circuit boards may include multiple heat-generating electronic components. For example, there may be multiple processors, in addition to any memory modules, capacitors, and so forth which operate at a higher temperature. In order to provide heat dissipation for the various components on a circuit board, a typical approach has been to fix an individual heatsink on each heat-generating component, with the dimensions and parameters of that heatsink tailored to the heat dissipation needs for that component. However, this may not always be practical, such as when the circuit board is too small to fit numerous individual heatsinks or when two components are right next to each other. At the same time, it may be undesirable to affix a single, large heatsink to multiple components. Rather than dissipate heat from all contacting components, a large heatsink may transfer excessive heat from one component to another. Furthermore, the various components of the circuit board may have varying heights and dimensions which makes it difficult to use a single heatsink. Therefore, there exists a need for a large unitary heatsink or assembly that can be used with components of varying heights and dimensions without transferring heat between those components.

### BRIEF SUMMARY OF THE INVENTION

Embodiments of this disclosure address these problems and more. In particular, this disclosure relates to a modular, floating core heat sink assembly that includes a frame and one or more floating core heat sinks that can be dropped into apertures in the frame. The frame itself can be used to dissipate heat from certain components (e.g., memory modules) of the circuit board, while the individual floating core heatsinks can be used to dissipate heat from other components (e.g., processors). The floating core heatsinks are not in contact or thermal coupling to the frame, and they can also be used with components of varying heights. This allows the floating core heatsinks to function as individual isolated heatsinks while being part of a single assembly. The entire assembly draws heat away from the heat-generating components of the circuit board and towards the cooling fins located on the floating core heatsinks.

The present disclosure relates generally to a floating core heatsink assembly which includes a frame having one or more apertures. One side of the frame may be configured to be mounted against a circuit board. In some embodiments, the frame itself may be configured to contact a component of the circuit board (either directly or indirectly, such as through a layer of thermal interface material). Thus, the frame itself acts as a heatsink or heat spreader that can dissipate heat from that component.

The floating core heatsink assembly may also include one or more floating core heatsinks, which are sized to be able to fit in the apertures of the frame. The apertures of the frame may be configured to be positioned over heat-generating components of the circuit board once the frame is mounted against the circuit board. This allows the floating core heatsinks to be dropped into the apertures of the frame to be placed into contact with the heat-generating components of the circuit board, with each individual floating core heatsink being in contact with an individualized component. The floating core heatsinks serve to dissipate heat from the components by transferring the heat towards the cooling fins located on the other side of the heatsinks. In some embodiments, the floating core heatsinks may be considered “floating” because the heatsinks are not thermally coupled to one another or the frame. Thus, each floating core heatsink serves to dissipate only the heat generated by the individual component with which it is in contact.

In some embodiments, each floating core heatsink may be coupled to the frame via one or more fasteners, which can be used to apply a downward force on the floating core heatsink to ensure proper contact between the heatsink and the component of the circuit board. Since each floating core heatsink is movable along the Z-axis once dropped into the corresponding aperture of the frame, the floating core heatsink can be adjusted to the height of the component. This allows the floating core heatsink to be used with circuit boards having components of varying heights.

One advantage of the embodiments of the floating core heatsink assembly described herein is that it can be used with circuit boards in place of having multiple, individual heatsinks for the many components on the circuit board. It can also be used with a circuit board having various types of components which have different heights and different heat outputs since the floating core heatsinks are not thermally coupled to one another or to the frame. Furthermore, the frame of the floating core heatsink assembly has short standoffs which can act as a stiffener for the circuit board to prevent a bowing effect in the circuit board, when placed under loading. The floating core heatsink assembly is also usable with lid-less packages, since the use of spring-loaded fasteners for attaching the floating core heatsinks ensures an even force distribution exerted on the die. Furthermore, selection of different springs with different spring rates makes it possible to apply a variety of compression forces between each heatsink and die, as needed. Finally, the individual floating core heatsinks are upgradable to different designs based on the needs of the particular component being cooled by that heatsink.

In some embodiments, the floating core heatsink assembly may include a frame adapted to be fastened to a circuit board and a first floating core heatsink adapted to fit within the first aperture of the frame. The frame may be configured to thermally couple with a first component on a circuit board when the frame is fastened to the circuit board. The location of the first aperture may be configured such that the first aperture is positioned over a second component on the circuit board when the frame is fastened to the circuit board. The first floating core heatsink is not thermally coupled to the frame when the first floating core heatsink is coupled with the second component.

In various embodiments, the frame further comprises a second aperture. The location of the second aperture may be configured such that the second aperture is positioned over a third component on the circuit board when the frame is fastened to the circuit board. The floating core heatsink assembly may further include a second floating core heatsink adapted to fit within the second aperture of the frame, and the second floating core heatsink is not thermally coupled to the frame when the second floating core heatsink is coupled with the third component. The frame may include a layer of thermal interface material (TIM) on a side of the frame, the layer of thermal interface material configured to interface with the first component when the frame is fastened to the circuit board. The first floating core heatsink may also comprise a set of cooling fins on a first side of the first floating core heatsink. In some embodiments, the first floating core heatsink comprises at least one heat pipe coupled with a second side of the first floating core heatsink, while in other embodiments, the first floating core heatsink comprises a vapor chamber coupled with a second side of the first floating core heatsink.

In various embodiments, the first floating core heatsink is coupled to the frame through at least one fastener that applies a spring force on the first floating core heatsink. The spring force may be adjustable. In some embodiments, the fastener comprises a screw adapted to pass through an aperture of a standoff located on the frame and a spring between a head of the screw and the first floating core heatsink. In some embodiments, the spring force is between the first floating core heatsink and the second component and causes the first floating core heatsink to be pushed away from the frame and against the second component when the first floating core heatsink is fastened to the frame.

In various embodiments, the first component is a memory module, the second component is a processor, and the third component is another processor. One or more of the first component, the second component, or the third component may be of different heights.

In various embodiments, the second floating core heatsink comprises a set of cooling fins on a first side of the second floating core heatsink. In some embodiments, the second floating core heatsink comprises at least one heat pipe coupled with a second side of the second floating core heatsink, while in other embodiments, the second floating core heatsink comprises a vapor chamber coupled with a second side of the first floating core heatsink.

In various embodiments, the frame further comprises a third aperture. The third aperture is positioned over a fourth component on the circuit board when the frame is fastened to the circuit board. The floating core heatsink assembly further comprises a third floating core heatsink adapted to fit within the third aperture of the frame and to be fastened to the frame. The third floating core heatsink is not thermally coupled to the frame when the third floating core heatsink is coupled with the fourth component.

In various embodiments, the frame comprises a set of cooling fins disposed on a top side of the frame, a set of long standoffs on a top side of the frame, and a set of short standoffs on a bottom side of the frame. In some embodiments, the set of short of short standoffs are configured to provide a spacing between the frame and the circuit board when the frame is fastened to the circuit board. In some embodiments, the spacing fits the layer of thermal interface material interfaced with the first component when the frame is fastened to the circuit board.

The above summarized embodiments are described in further detail below in conjunction with the following drawings.

### BRIEF DESCRIPTION OF THE DRAWINGS

FIG. 1 illustrates a top perspective view of a printed circuit board in accordance with embodiments of the present disclosure.

FIG. 2A illustrates a top perspective view of a frame in accordance with embodiments of the present disclosure.

FIG. 2B illustrates a top view of a frame in accordance with embodiments of the present disclosure.

FIG. 2C illustrates a top perspective view of a frame and fasteners in accordance with embodiments of the present disclosure.

FIG. 3A illustrates a top perspective view of a frame and a printed circuit board in accordance with embodiments of the present disclosure.

FIG. 3B illustrates a top perspective view of a frame and a printed circuit board in accordance with embodiments of the present disclosure.

FIG. 3C illustrates a bottom perspective view of a frame and a transparent printed circuit board in accordance with embodiments of the present disclosure.

FIG. 3D illustrates a bottom perspective view of a frame, a transparent printed circuit board, and fasteners, in accordance with embodiments of the present disclosure.

FIG. 4A illustrates a bottom perspective view of a floating core heatsink in accordance with embodiments of the present disclosure.

FIG. 4B illustrates a bottom perspective view of another floating core heatsink in accordance with embodiments of the present disclosure.

FIG. 4C illustrates a bottom perspective view of another floating core heatsink in accordance with embodiments of the present disclosure.

FIG. 4D illustrates a bottom perspective view of another floating core heatsink in accordance with embodiments of the present disclosure.

FIG. 5A illustrates an exploded bottom perspective view of a floating core heatsink assembly that includes two floating core heatsinks and a frame, in accordance with embodiments of the present disclosure.

FIG. 5B illustrates an exploded bottom perspective view of another floating core heatsink assembly that includes two floating core heatsinks and a frame, in accordance with embodiments of the present disclosure.

FIG. 5C illustrates an exploded top perspective view of the floating core heatsink assembly of FIG. 5A, in accordance with embodiments of the present disclosure.

FIG. 5D illustrates a top perspective view of the floating core heatsink assembly of FIG. 5A, in accordance with embodiments of the present disclosure.

FIG. 5E illustrates a side view of the floating core heatsink assembly of FIG. 5A when mounted for use, in accordance with embodiments of the present disclosure.

FIG. 5F illustrates a side view of the floating core heatsink assembly of FIG. 5B when mounted for use, in accordance with embodiments of the present disclosure.

FIG. 6A illustrates an exploded top perspective view of a floating core heatsink assembly that includes two floating core heatsinks and a frame, in accordance with embodiments of the present disclosure.

FIG. 6B illustrates springs being dropped into the heatsinks of FIG. 6A in order to receive fasteners, in accordance with embodiments of the present disclosure.

FIG. 6C illustrates fasteners being dropped into the heatsinks of FIG. 6B, in accordance with embodiments of the present disclosure.

FIG. 6D illustrates the floating core heatsink assembly of FIG. 6C mounted for use.

FIG. 6E illustrates a sectional view through some of the fasteners used with a floating core heatsink assembly in accordance with embodiments of the present disclosure.

### DETAILED DESCRIPTION OF THE INVENTION

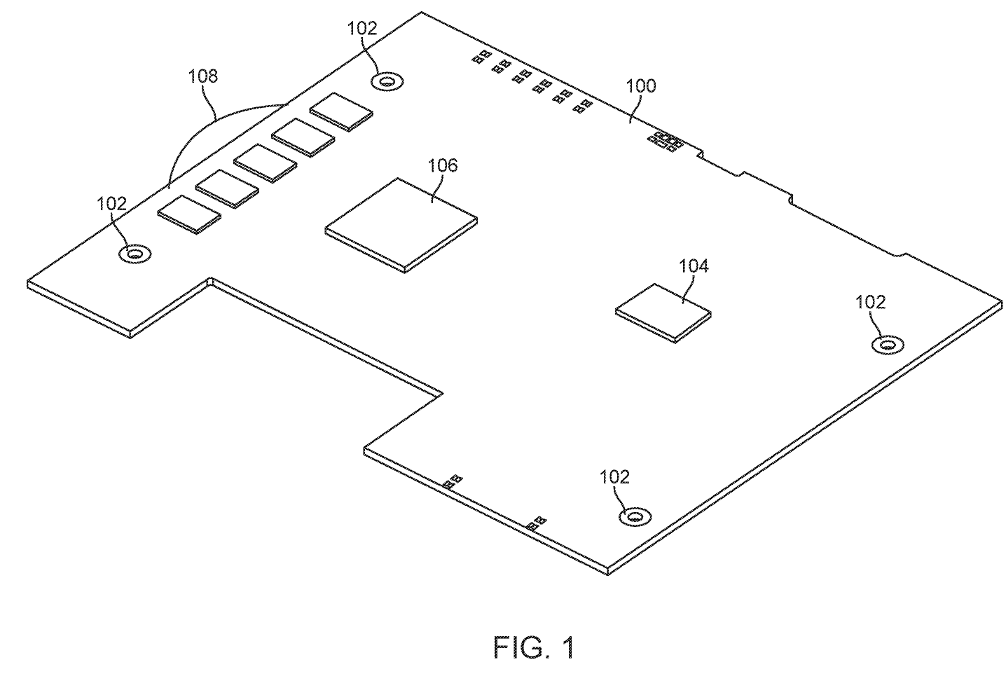

FIG. 1 illustrates a top perspective view of a printed circuit board in accordance with embodiments of the present disclosure.

In some embodiments, a printed circuit board (PCB) 100 may have one or more powered, heat-producing components that may need cooling. For example, in some embodiments such as the one depicted in the figure, the PCB 100 may have a first processor 106 and a second processor 104. In some embodiments, the PCB 100 may also have a chip bank or array of memory 108. Accordingly, in the embodiment depicted in the figure, the first processor 106, the second processor 104, and the memory 108 may all be heat-producing components.

In some embodiments, the PCB 100 may also have a set of apertures 102 (e.g., openings) which have a size and configuration for receiving fasteners (e.g., mounting screws) for mounting a frame (not pictured) to the PCB 100. In the embodiment shown in the figure, there are four apertures 102 that are positioned towards the corners/edges of the PCB 100. However, there may be any number of apertures 102 and they may be positioned anywhere on the PCB 100, not just towards the corners of the PCB 100.

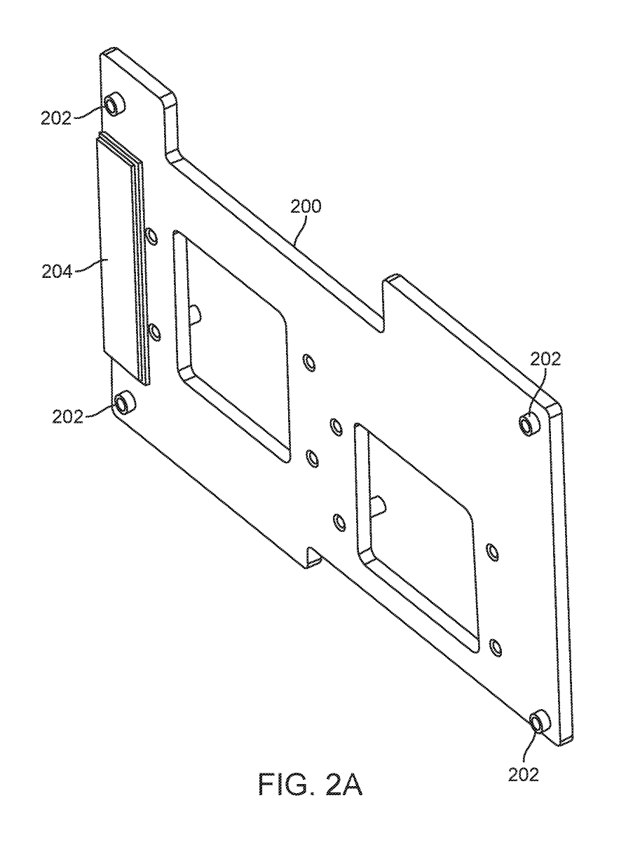

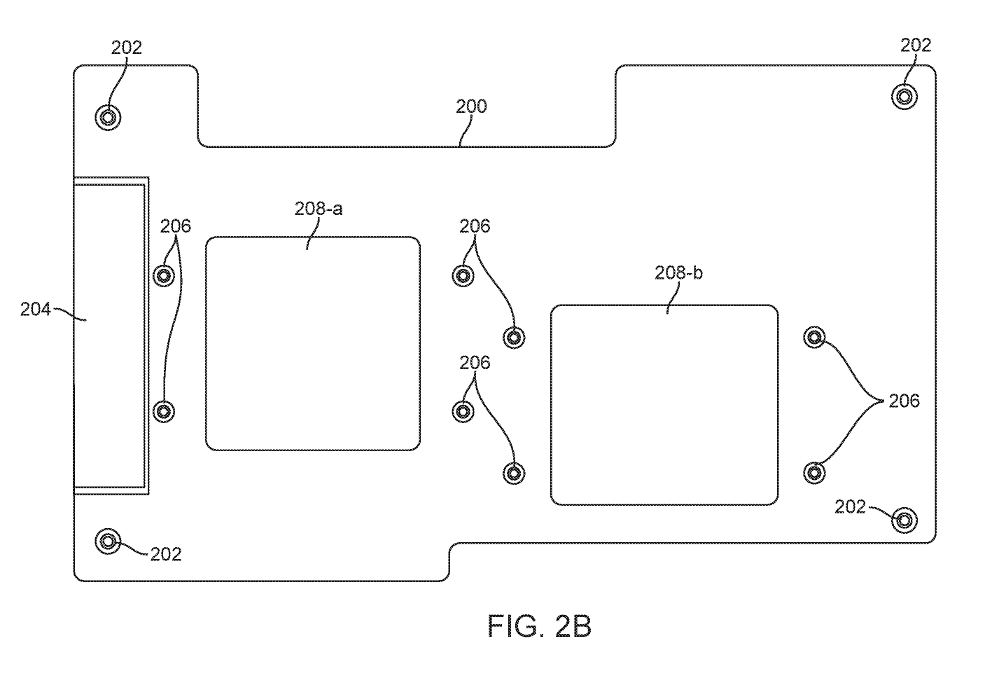

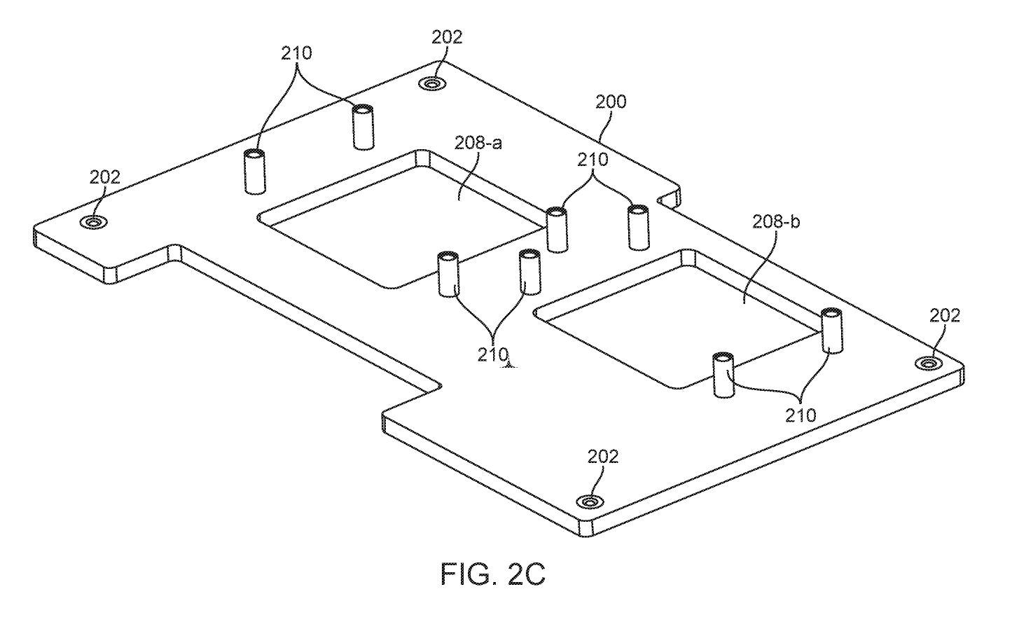

FIG. 2A illustrates a top perspective view of a frame in accordance with embodiments of the present disclosure. FIG. 2B illustrates a top view of a frame in accordance with embodiments of the present disclosure. FIG. 2C illustrates a top perspective view of a frame and fasteners in accordance with embodiments of the present disclosure. The following description of the frame is provided in reference to all three sub-figures.

In some embodiments, the frame 200 may have a set of standoffs 202. In some embodiments, the standoffs 202 are relatively short (e.g., shorter than standoffs 210) and may be referred to as short standoffs. The standoffs 202 may be located on the frame 200 at positions that correspond to the apertures 102 of the PCB 100 once the frame 200 and the PCB 100 are pressed together. The standoffs 202 may help serve to securely fasten the frame 200 to the PCB 100 by receiving fasteners (e.g., mounting screws). The standoffs 202 may extend outwards on the side of the frame 200 with the heat spreader 204. The standoffs 202 may each have an aperture 203 for receiving a fastener (e.g., a mounting pin or mounting screw).

In some embodiments, the frame 200 will be positioned over the PCB 100 with the standoffs 202 facing downwards. Between the peripheral memory modules 108 of the PCB 100 and the frame 200 may be a layer of thermal interface material (TIM). The thermal interface material may comprise any material used to fill the gaps between thermal transfer surfaces, such as between components and heatsinks, in order to increase thermal transfer efficiency. In some embodiments, the layer of thermal interface material may initially reside on the frame 200, while in other embodiments, a user may have to manually apply the layer of thermal interface material (e.g., by applying it to the memory modules 108 or to the frame 200). The short standoffs 202 may provide the proper spacing between the frame 200 and the PCB 100 to allow for the height of the memory modules 108 combined with the thickness of thermal interface material, thus allowing the memory modules 108 and thermal interface material to be sandwiched between the frame 200 and the PCB 100. In some embodiments, fasteners (e.g., mounting screws) can be inserted into the standoffs 202 from the bottom of the PCB 100 (e.g., the mounting screws can be inserted upwards).

In some embodiments, the frame 200 may have a heat spreader 204 located on the frame 200 at a position that corresponds to the memory modules 108 of the PCB 100 once the frame 200 and the PCB 100 are pressed together. In such embodiments, the short standoffs 202 may provide the proper spacing between the heat spreader 204 and the PCB 100 to allow for the height of the memory modules 108 combined with the thickness of thermal interface material, thus allowing the memory modules 108 and thermal interface material to be sandwiched between the frame 200 and the heat spreader 204 of PCB 100.

In some embodiments, the frame 200 may have a set of standoffs 210 for accepting one or more floating core heatsinks. More specifically, the standoffs 210 may be pressed into the frame 200 at specific locations for guiding and accepting the placement of the individual floating core heatsinks (e.g., the first heatsink 400 and the second heatsink 420, not shown in FIGS. 2A-2C). In some embodiments, the standoffs 210 are relatively long (e.g., longer than the standoffs 202) and may be referred to as long standoffs. The standoffs 210 may extend outwards on the other side of the frame 200 as the standoffs 202. The standoffs 210 may each have an aperture 206 for receiving a fastener (e.g., a mounting pin or mounting screw).

In some embodiments, the frame 200 may have one or more slots or apertures (e.g., aperture 208-a and aperture 208-b) that are each configured for receiving a floating core heatsink. The apertures do not need to all be the same dimensions. The apertures can vary in dimension and each individual floating core heatsink may be configured with dimensions to fit within a corresponding aperture. As shown in the figures, the embodiment of frame 200 has two apertures for receiving two floating core heatsinks. In some embodiments, frame 200 may have three apertures for receiving three floating core heatsinks. In some embodiments, frame 200 may have more than three apertures, with each aperture available to receive a floating core heatsink.

In some embodiments, the frame 200 may be made of any material adapted to absorb and dissipate heat from another object, such as a component on a circuit board. For example, the frame 200 may be made of a metal such as copper or aluminum. Thus, in cases where the frame 200 may be thermally coupled (either directly or indirectly, such as through a layer of thermal interface material) with the memory modules 108, the frame 200 may draw heat away from the memory modules 108.

In some embodiments (not shown in the figure), frame 200 may have a set of cooling fins disposed on one side of the frame 200 (e.g., on the side opposite to the side of the frame 200 that would face the PCB 100). These cooling fins may be used to further cool and dissipate heat that the frame 200 has taken on from a component (e.g., memory modules 108). This may be useful for larger circuit boards which allow the frame 200 to have cooling fins while still retaining space for the floating core heatsinks. In such cases, the cooling fins on the frame 200 may be present in between the placed floating core heatsinks. In other words, the cooling fins may be present where the frame 200 would not be covered by the floating core heatsinks.

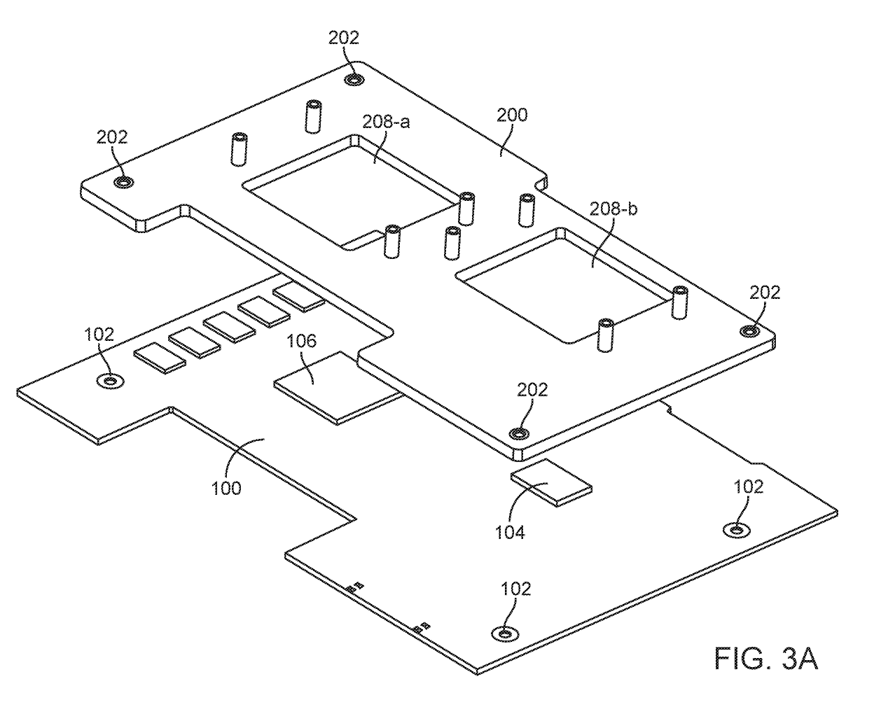

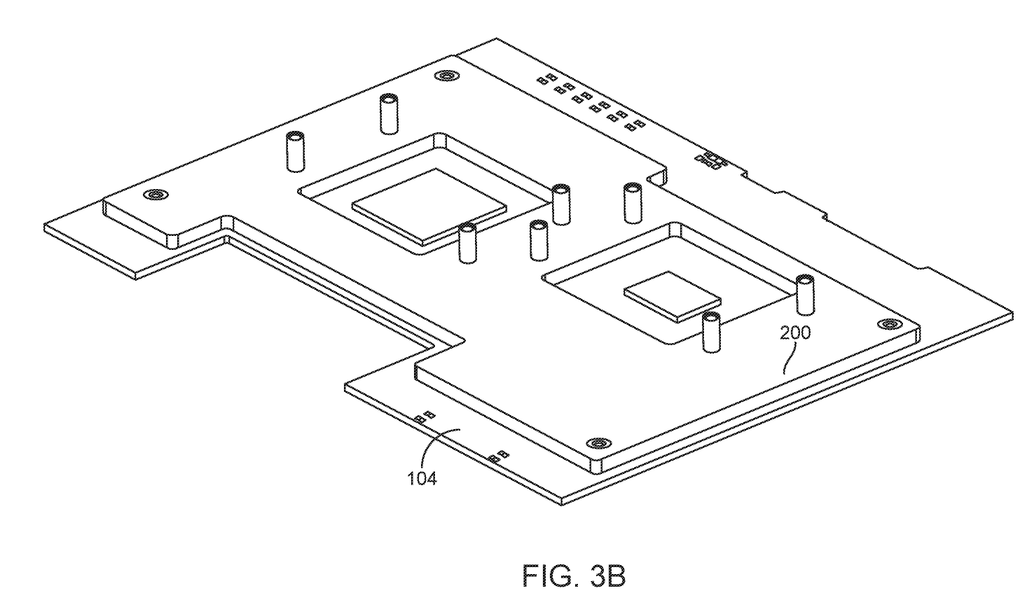

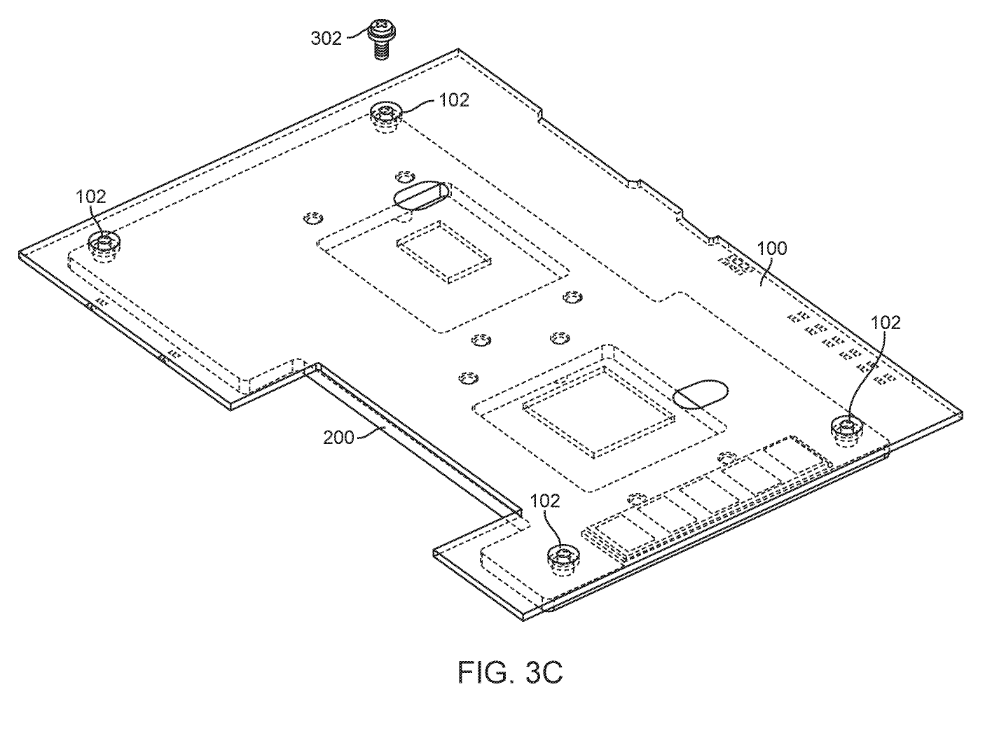

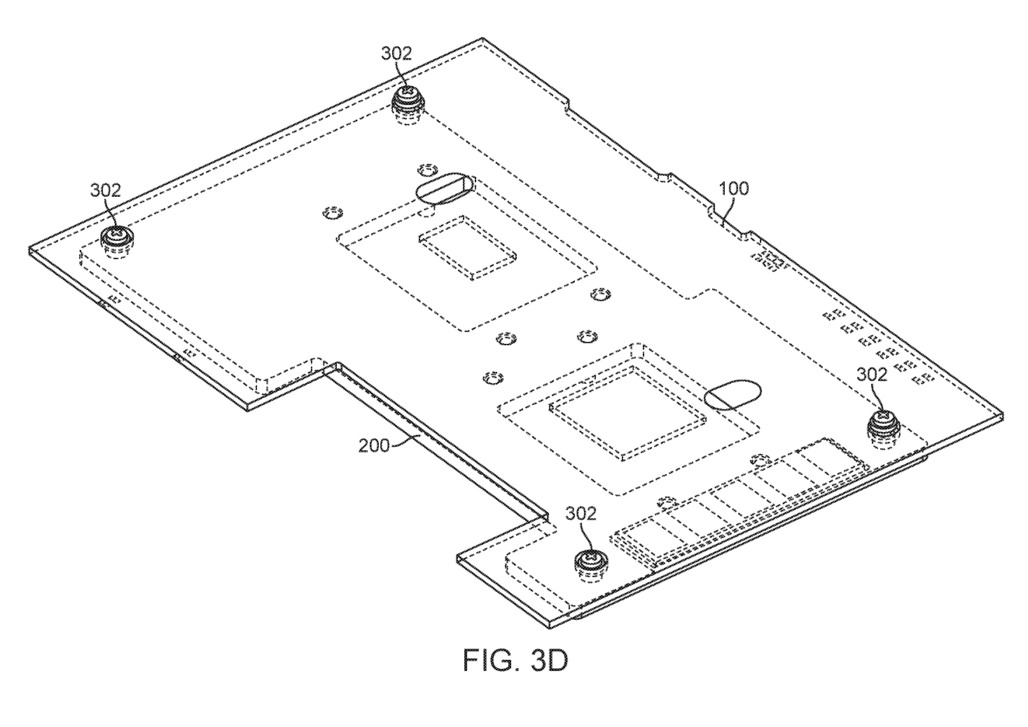

FIG. 3A illustrates a top perspective view of a frame and a printed circuit board in accordance with embodiments of the present disclosure. FIG. 3B shows a frame and a printed circuit board aligned against one another. FIG. 3C illustrates a bottom perspective view of a frame and a transparent printed circuit board in accordance with embodiments of the present disclosure. FIG. 3D illustrates a bottom perspective view of a frame, a transparent printed circuit board, and fasteners, in accordance with embodiments of the present disclosure. The following description of the frame and printed circuit board is provided in reference to all four sub-figures.

In FIG. 3A, the frame 200 is shown positioned over the printed circuit board (PCB) 100. The set of apertures 202 of the frame 200 are vertically aligned with the set of apertures 102 in the PCB 100. The first processor 106 on the PCB 100 is vertically aligned with the aperture 208-a of the frame 200. Similarly, the second processor 104 on the PCB 100 is vertically aligned with the aperture 208-b of the frame 200. Once the frame 200 is properly aligned with the PCB 100, the frame 200 can be lowered onto the PCB 100 as shown in FIG. 3B.

In order to fasten the frame 200 to the PCB 100, a set of fasteners 302 (e.g., mounting screws) may be used. FIG. 3C shows the frame 200 and PCB 100 together, flipped over so that the PCB 100 is on top. The PCB 100 is shown to be transparent in the figure for the purposes of facilitating understanding. The fasteners 302 are inserted into the apertures 102 in the PCB 100 (located on the bottom of the PCB 100) and the apertures 203 of the standoffs 202 of the frame 200, which are aligned with the apertures 102. Once all the fasteners 302 have been inserted, the frame 200 and PCB 100 will be assembled together as shown in FIG. 3D.

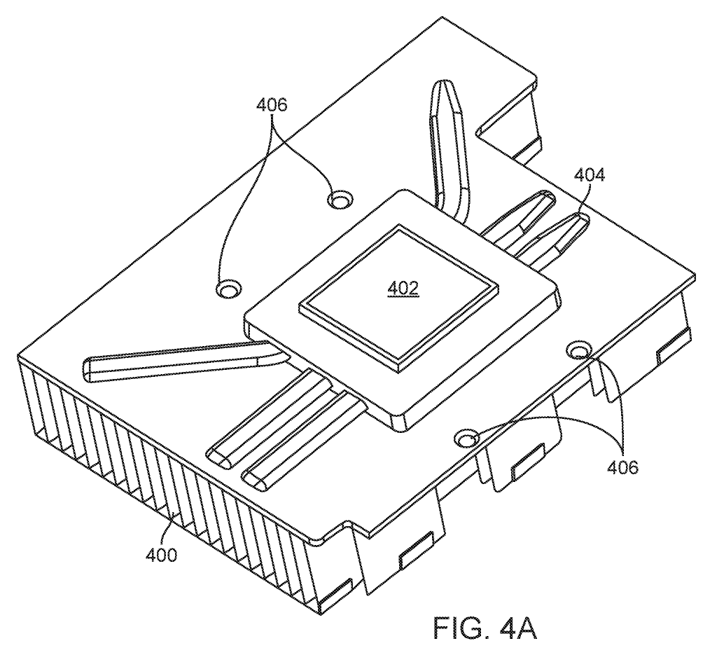

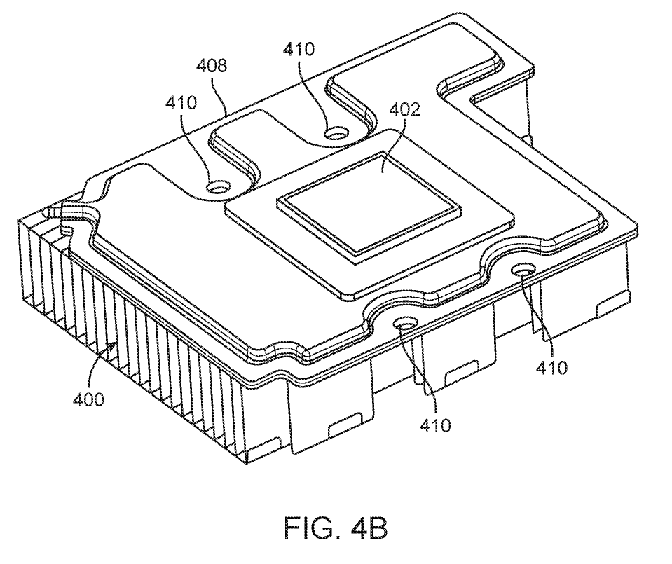

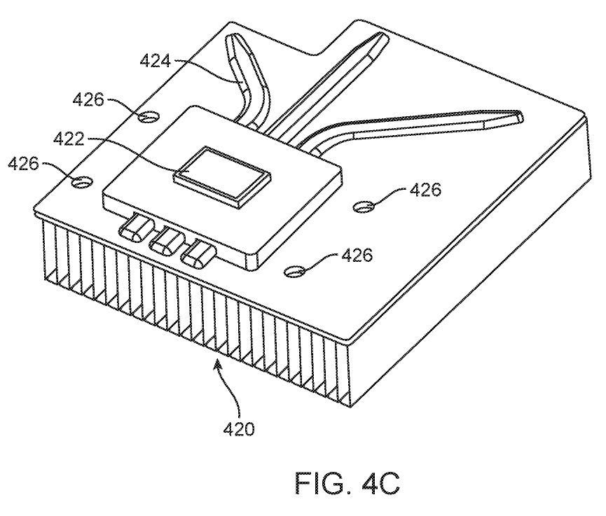

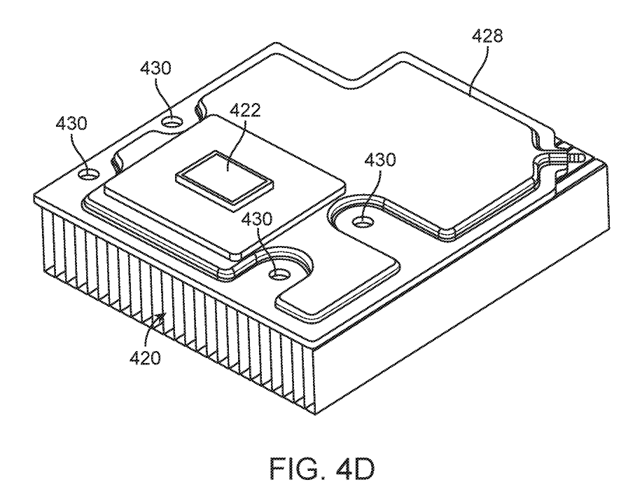

Once all the fasteners 302 have been fastened into the apertures 203 (sometimes referred to as mounting feet) of the standoffs 202, the frame 200 will be rigidly secured to the PCB 100. This may compress the thermal interface material (TIM) sandwiched between the memory modules 108 and the frame 200, which may help the TIM to conduct heat away from the memory modules 108 and into the frame 200. Once the frame 200 is mounted to the PCB 100, floating core heatsinks (e.g., the first heatsink 400 and the second heatsink 420 described in FIGS. 4A-4D) can be dropped into the apertures 208-a and 208-b in the frame 200. These heatsinks may have apertures or mounting holes which are used for sliding/locating purposes (e.g., to properly align the heatsinks to the frame 200).

FIG. 4A illustrates a bottom perspective view of a floating core heatsink in accordance with embodiments of the present disclosure. FIG. 4B illustrates a bottom perspective view of a different floating core heatsink in accordance with embodiments of the present disclosure. FIG. 4C illustrates a bottom perspective view of another floating core heatsink in accordance with embodiments of the present disclosure. FIG. 4D illustrates a bottom perspective view of yet another floating core heatsink in accordance with embodiments of the present disclosure. The following description of the heatsinks is provided in reference to all four sub-figures.

More specifically, FIGS. 4A and 4B illustrate a first and second design for a floating core heatsink. This floating core heatsink can be enhanced with heat pipes disposed at the bottom of the heatsink (as in the case of FIG. 4A), or it can be enhanced with a vapor chamber disposed at the bottom of the heatsink (as in the case of FIG. 4B). FIGS. 4C and 4D illustrate a third and fourth design for a floating core heatsink. This floating core heatsink can also be enhanced with heat pipes disposed at the bottom of the heatsink (as in the case of FIG. 4C), or it can be enhanced with a vapor chamber disposed at the bottom of the heatsink (as in the case of FIG. 4D).

In some embodiments, there may be a first heatsink 400. At the top, the first heatsink 400 may have cooling fins characteristic of heatsinks. The fins may create additional surface area to assist in dissipating heat to the surrounding environment. At the bottom of the first heatsink 400 may be a first heat spreader 402. In some embodiments, the first heat spreader 402 may be a high polish, flat contact surface for the processor. In some embodiments, the first heat spreader 402 may receive thermal interface material (e.g., thermal grease or a thermal pad). In some embodiments, such as the embodiment shown in FIG. 4A, extending outward from the first heat spreader 402 may be one or more heat pipes 404. The heat pipes 404 may each comprise a sealed hollow tube formed of heat conductive metal, such as copper or aluminum, and filled with a small quantity of coolant and vapor (e.g., water and water vapor). The heat pipes 404 may serve to redistribute heat at the first heat spreader 402 (e.g., from a component in contact with the first heat spreader 402) throughout the first heatsink 400. In some embodiments, the first heatsink 400 may have a set of apertures 406 which can receive fasteners used to mount the first heatsink 400 to the frame 200.

In some embodiments, such as the embodiment shown in FIG. 4B, the bottom of the first heatsink 400 may be a vapor chamber 408. In some embodiments, the first heatsink 400 may have a set of apertures 410 which can receive fasteners used to mount the first heatsink 400 to the frame 200.

In some embodiments, there may be a second heatsink 420. The second heatsink 420 may also have cooling fins characteristic of heatsinks. At the bottom of the second heatsink 420 may be a second heat spreader 422. In some embodiments, the first heat spreader 402 may be a high polish, flat contact surface for the processor. In some embodiments, the first heat spreader 402 may receive thermal interface material (e.g., thermal grease or a thermal pad). In some embodiments, such as the embodiment shown in FIG. 4C, extending outward from the second heat spreader 422 may be one or more heat pipes 424. The heat pipes 424 may serve to redistribute heat at the second heat spreader 422 (e.g., from a component in contact with the second heat spreader 422) throughout the second heatsink 402. In some embodiments, the second heatsink 420 may have a set of apertures 426 which can receive fasteners used to mount the second heatsink 420 to the frame 200.

In some embodiments, such as the embodiment shown in FIG. 4D, the bottom of the second heatsink 420 may be a vapor chamber 428. In some embodiments, the second heatsink 420 may have a set of apertures 430 which can receive fasteners used to mount the second heatsink 420 to the frame 200.

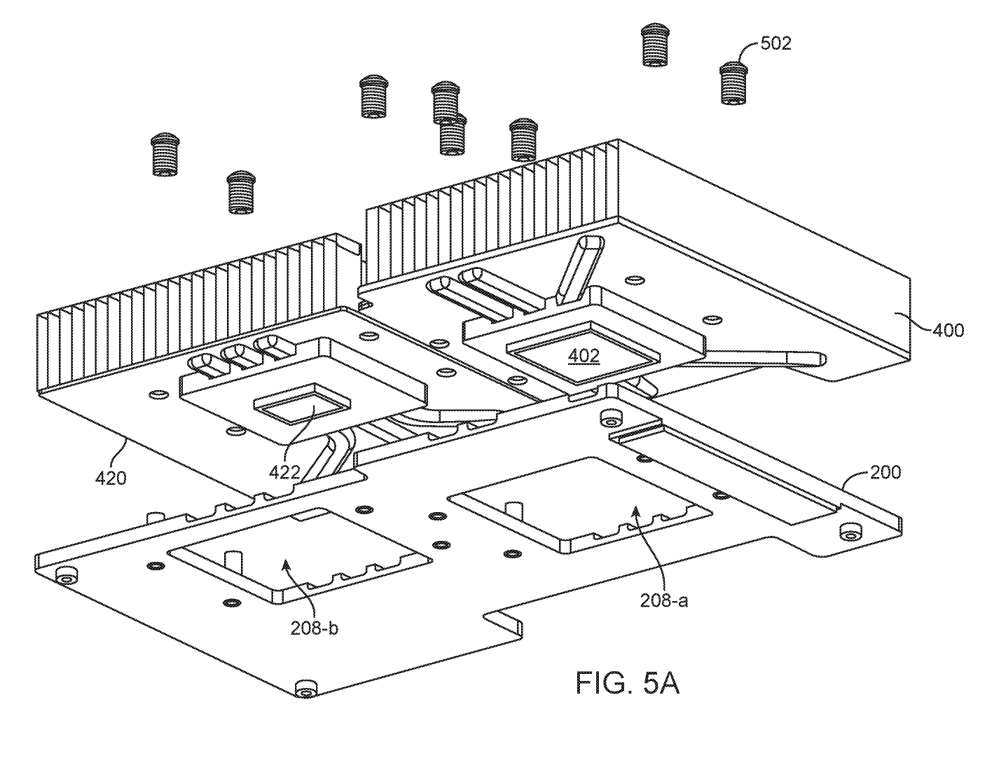

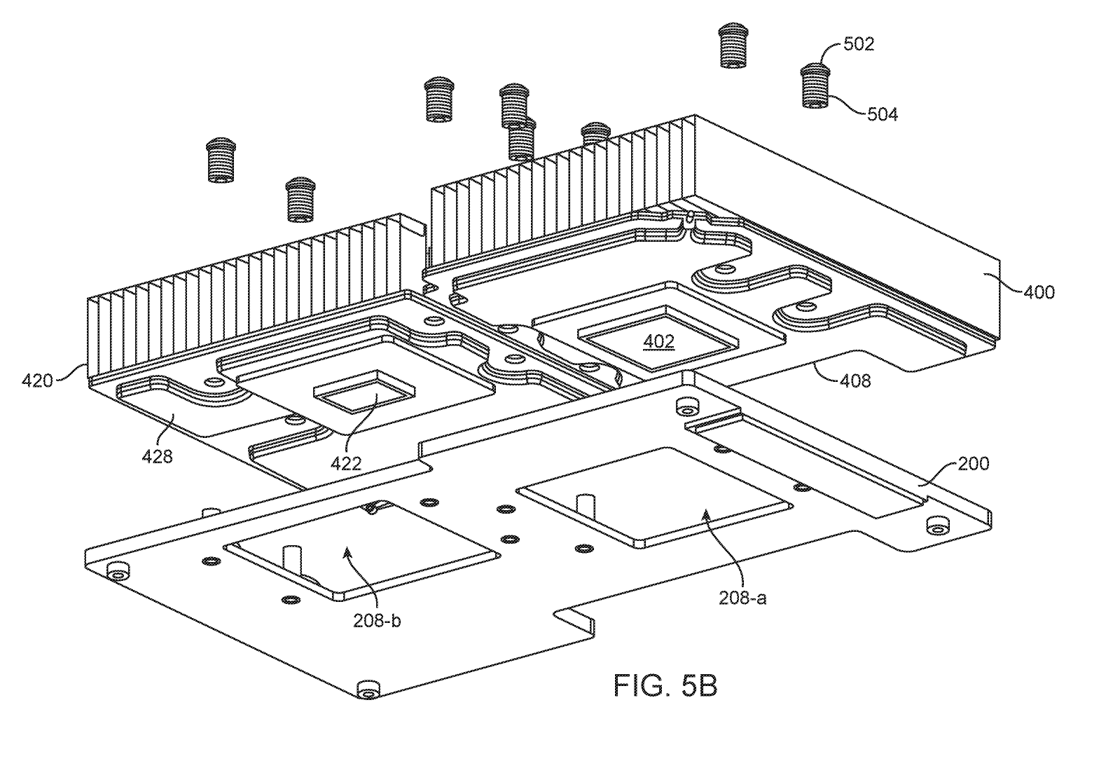

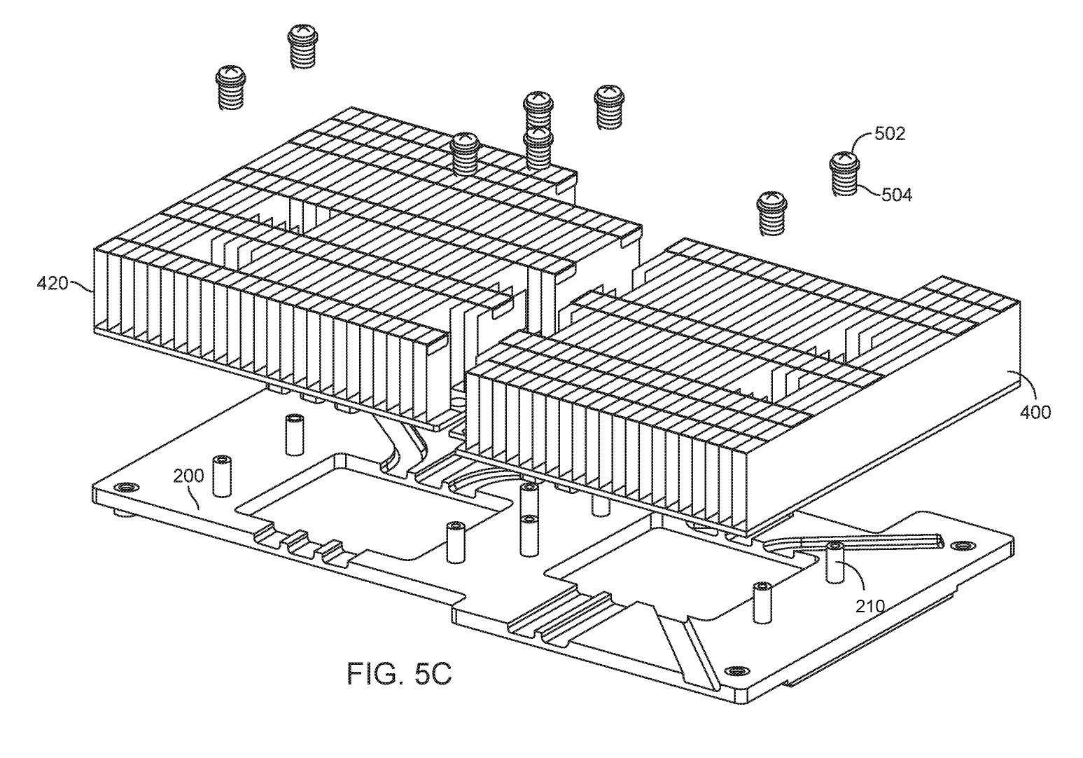

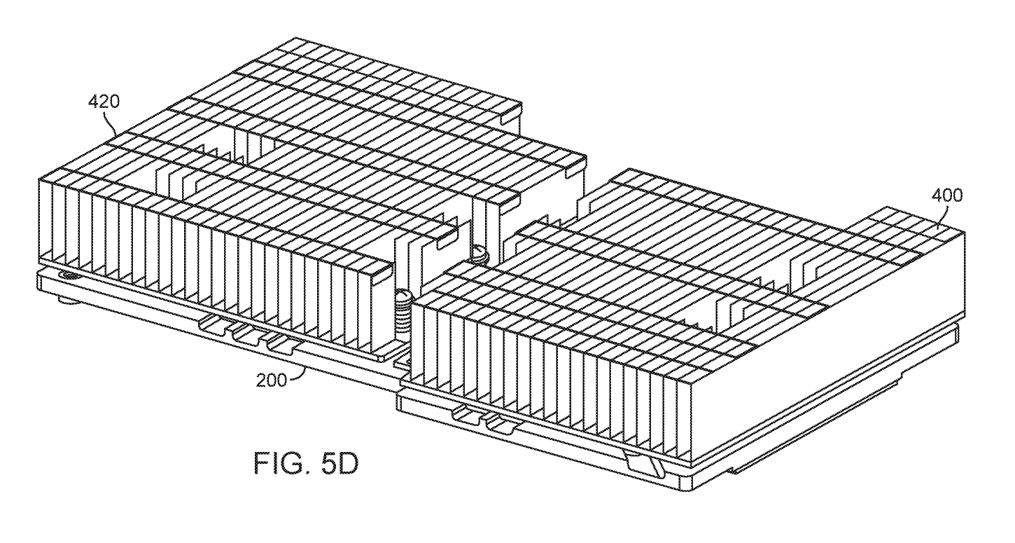

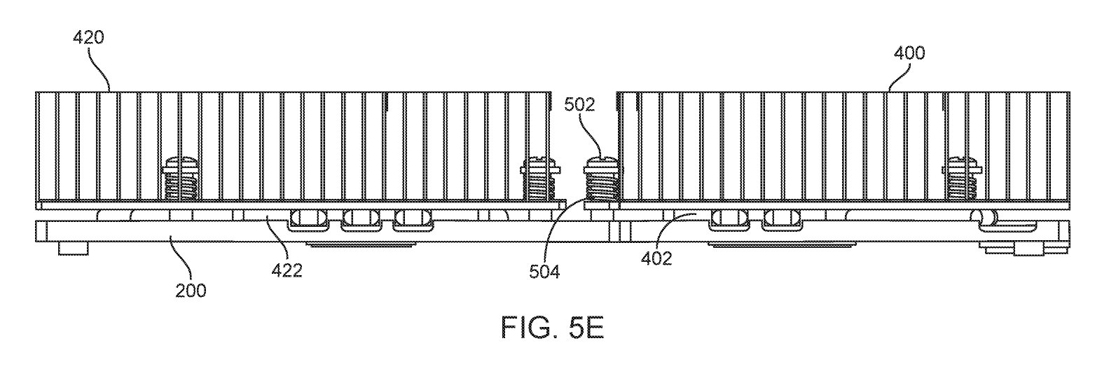

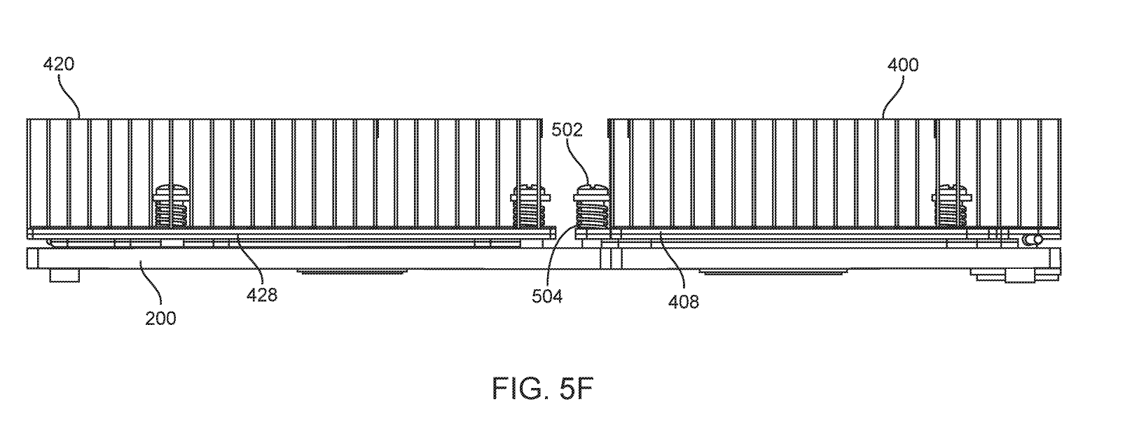

FIG. 5A illustrates an exploded bottom perspective view of a floating core heatsink assembly that includes two floating core heatsinks and a frame, in accordance with embodiments of the present disclosure. FIG. 5B illustrates an exploded bottom perspective view of another floating core heatsink assembly that includes two floating core heatsinks and a frame, in accordance with embodiments of the present disclosure. FIG. 5C illustrates an exploded top perspective view of the floating core heatsink assembly of FIG. 5A, in accordance with embodiments of the present disclosure. FIG. 5D illustrates a top perspective view of the floating core heatsink assembly of FIG. 5A, in accordance with embodiments of the present disclosure. FIG. 5E illustrates a side view of the floating core heatsink assembly of FIG. 5A when mounted for use, in accordance with embodiments of the present disclosure. FIG. 5F illustrates a side view of the floating core heatsink assembly of FIG. 5B when mounted for use, in accordance with embodiments of the present disclosure. The following description of the heatsinks and frame is provided in reference to all six sub-figures.

FIG. 5A shows the first heatsink 400 and the second heatsink 420 arranged over the frame 200. The first heat spreader 402 is positioned over the aperture 208-a, while the second heat spreader 422 is positioned over the aperture 208-b. Once the first heatsink 400 and the second heatsink 420 are lowered onto the frame 200, the first heat spreader 402 will slide into the aperture 208-a and the second heat spreader 422 will slide into the aperture 208-b. The standoffs 210 on the frame 200 can be used to locate the proper positions for the heat spreaders. In some embodiments, there may be thermal interface material (TIM) on the bottom of the heat spreaders (e.g., the first heat spreader 402 and the second heat spreader 422). Once the first heatsink 400 and the second heatsink 420 are lowered and the first heat spreader 402 and the second heat spreader 422 are seated, the thermal interface material may compress and contact the processors underneath (e.g., processors 106 and 104). Accordingly, the dimensions of the aperture 208-a will be similar to that of the first heat spreader 402 in order to receive the first heat spreader 402, and the dimensions of the aperture 208-b will be similar to that of the second heat spreader 422 in order to receive the second heat spreader 422.

In the figure shown, the Z-axis may be directed along the length of the fasteners 502, while the X-axis may span along the length of the frame 200, leaving then Y-axis to span along the width of the frame 200. Since the first heat spreader 402 will have similar dimensions relative to the aperture 208-a, the first heat spreader 402 (and thus, the first heatsink 400) may be movable up and down along the Z-axis within the aperture 208-a. Similarly, the second heat spreader 422 (and thus, the second heatsink 420) may be moveable up and down along the Z-axis within the aperture 208-b. This allows the first heatsink 400 to be lowered until the first heat spreader 402 makes contact with the component underneath, regardless of the height of that component. Since the second heatsink 420 is completely independent of the first heatsink 400, the second heatsink 420 can also be lowered until the second heat spreader 422 makes contact with the component underneath, regardless of the height of that component (and even if the height differs from the height of the component under the first heat spreader 402). If the two components are different heights, then the first heat spreader 402 and second heat spreader 422 will just be seated on different Z-plans.

In some embodiments, a set of fasteners 502 (e.g., mounting screws) can be lowered into the apertures of the first heatsink 400 and the second heatsink 420, and then through the standoffs 210 of the frame 200, which will fasten those heatsinks to the frame 200. In some embodiments, the fasteners 502 may be mounting screws that are sleeved with springs 504. In some embodiments, the springs 504 will first be dropped into the apertures of the first heatsink 400 and the second heatsink 420 to be positioned around the standoffs 210, and then the fasteners 502 will be inserted afterwards. The fasteners 502 are fastened to the threaded portion of the standoffs 210 which applies proper mounting pressure between the heatsinks and the frame/PCB to secure both heat spreaders to the assembly. It also applies downward pressure on the two heatsinks, thereby compressing the thermal interface material (e.g., at the bottom of both heat spreaders) against the processors 106 and 104.

This enables the second heatsink 420 and the first heatsink 400 to be neither thermally coupled to each other nor the frame 200. Once the second heatsink 420 and the first heatsink 400 are dropped into position and spring-based fasteners 502 are used to fasten them to the frame 200, the spring force causes the components under the second heatsink 420 and the first heatsink 400 (e.g., processors 104 and 106) to push up against the heat spreaders of their respective heatsinks. This pushes the heat spreader of each heatsink upwards such that the heat spreaders are sitting up and above the frame 200 and not making thermal contact with the frame 200. This means that each component (e.g., processors 104 and 106) is cooled independently since the second heatsink 420, the first heatsink 400, and the frame 200 are not in thermal contact. This allows the frame 200 to be used to cool a component, such as the memory modules 108, without the risk that heat from the processors 104 and 106 will transfer the memory modules 108 (and vice versa).

Thus, first heat spreader 402 will dissipate heat away from the processor 106 while the second heat spreader 422 will dissipate heat away from the processor 104. In some embodiments, the heatsinks may be designed such that the two heat spreaders each have a set of heatpipes redistributing that heat throughout the respective heatsink. In other embodiments, such as the embodiment shown in FIG. 5B, the first heatsink 400 and the second heatsink 420 will have vapor chamber 408 and vapor chamber 428, respectively, integrated on the bottom of the heatsink to draw heat away from the heat spreaders or contact surfaces.

FIG. 5E and FIG. 5F provide a side view of the first heatsink 400 and the second heatsink 420 once they have been attached to the frame 200.

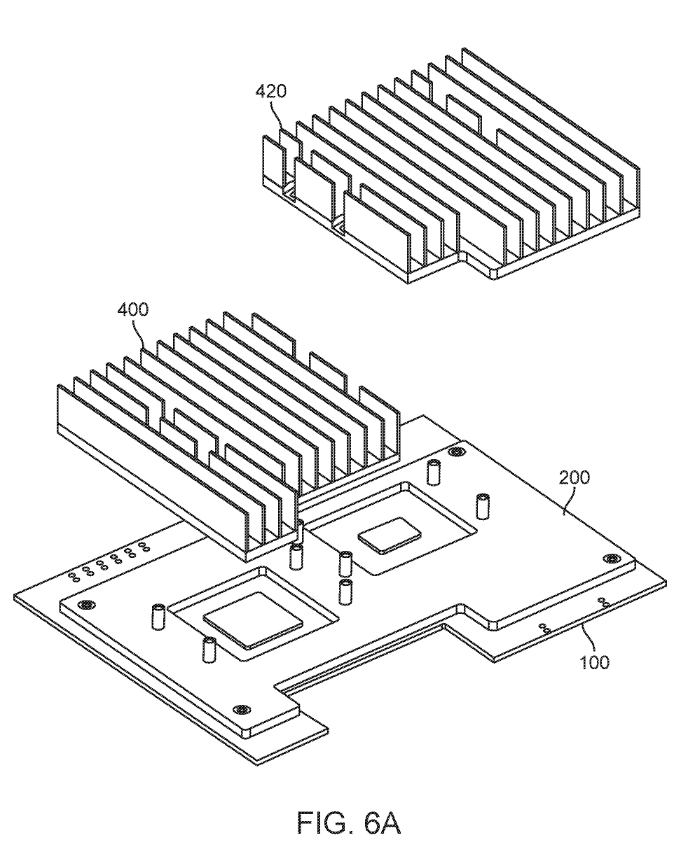

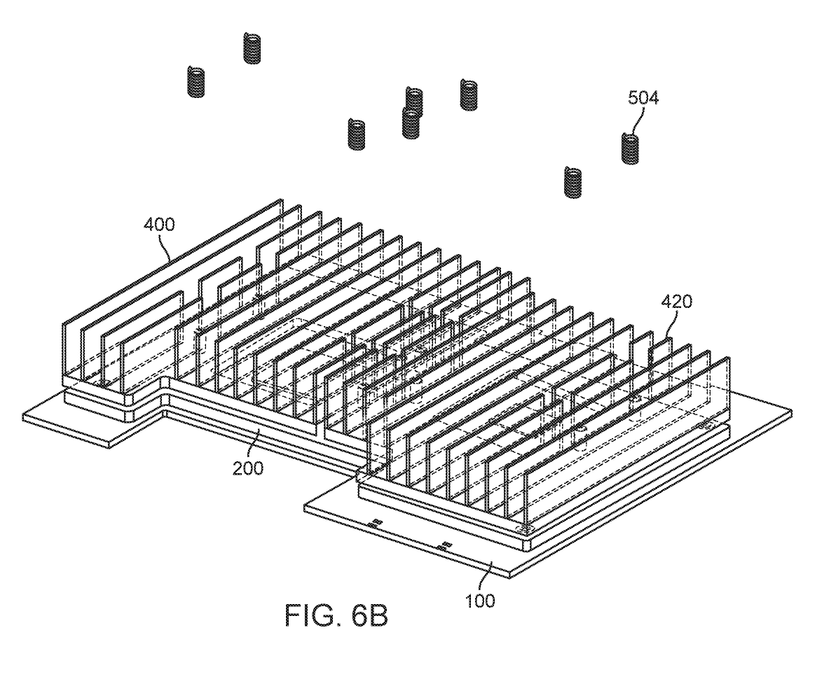

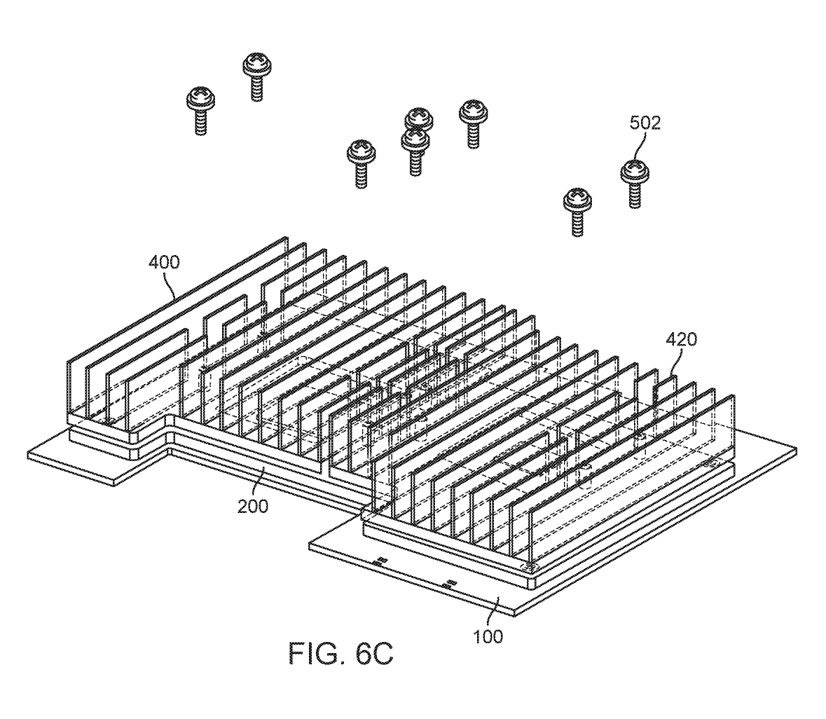

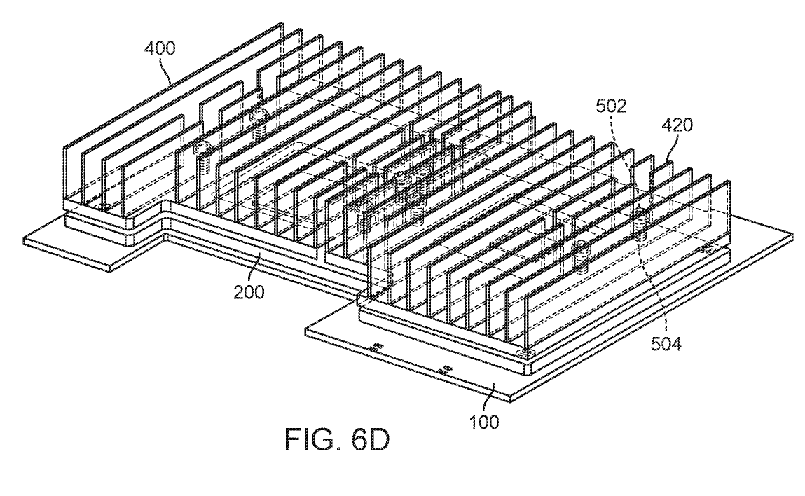

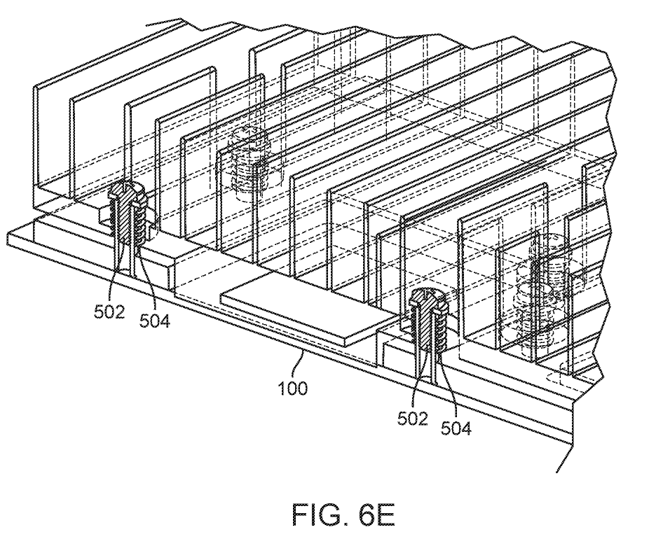

FIG. 6A illustrates an exploded top perspective view of a floating core heatsink assembly that includes two floating core heatsinks and a frame, in accordance with embodiments of the present disclosure. FIG. 6B illustrates springs being dropped into the heatsinks of FIG. 6A in order to receive fasteners, in accordance with embodiments of the present disclosure. FIG. 6C illustrates fasteners being dropped into the heatsinks of FIG. 6B, in accordance with embodiments of the present disclosure. FIG. 6D illustrates the floating core heatsink assembly of FIG. 6C mounted for use. FIG. 6E illustrates a sectional view through some of the fasteners used with a floating core heatsink assembly in accordance with embodiments of the present disclosure. The following description of the heatsinks and frame is provided in reference to all five sub-figures.

In FIG. 6A, the first heatsink 400 and the second heatsink 420 are shown over the frame 200 which has been attached to the printed circuit board (PCB) 100. In FIG. 6B, the fasteners 502 (e.g., mounting screws) and their corresponding springs 504 are inserted into the first heatsink 400 and the second heatsink 420 in order to attach them to the frame 200. By sleeving each mounting screw with a spring, the heatsinks are able to be easily attached to the frame 200 without the first heat spreader 402 or second heat spreader 422 being crushed. Thus, the mounting screw can be tightened onto the corresponding spring. The strength of this spring may be referred to as the spring constant, which may dictate how much spring force is applied to the heatsink in the downward Z-direction (e.g., pushing the heatsink into the component underneath). The amount of spring force being applied on the heatsink may be adjustable and determined by selecting a spring with the desired spring constant.

In some embodiments, the springs 504 may serve to ensure an even, balanced, force load is being applied to the component by the heatsink in the downward Z-direction. This may prevent damage or crushing of the component. This can especially be a problem for components that are lid-less. Sometimes, covers or lids on a component are removed or are omitted during fabrication. Lids are formed on components to protect the fragile components from damage. The lid of a component, commonly formed from aluminum or plastic, may have thermal impedance that negatively affects the dissipation of heat from the active component underneath the lid. Thus, the lids are sometimes removed, or are omitted during fabrication, so that the heat sink can directly contact the active element instead of contacting the lid. However, when the lid is removed, the component is very susceptible to damage and uneven force distribution (which is prevented by the springs) can lead to component damage.

Also, as previously mentioned, the spring force from the springs 504 serve to push the components against the contact surfaces or heats spreaders of the second heatsink 420 and the first heatsink 400. This pushes the heat spreader of each heatsink upwards such that the heat spreaders (e.g., the first heat spreader 402 or second heat spreader 422) are sitting above the frame 200 and no longer making thermal contact with the frame 200. In this state, the second heatsink 420, the first heatsink 400, and the frame 200 are not in thermal contact with one another. This allows the components of the circuit board to be cooled independently. For instance, the first heatsink 400 can cool processor 106, the second heatsink 420 can cool processor 104, and the frame 200 can be used to cool memory modules 108.

FIG. 6D shows the first heatsink 400 and the second heatsink 420 once they been properly attached to the frame 200 and PCB 100.

FIG. 6E shows the fasteners 502 (e.g., mounting screws) and their corresponding springs 504 once they have been inserted into the heatsinks and the long standoffs 210 on frame 200. The fasteners 502 will tread down while compressing the springs 504, until the screw washer head mates with the top of the standoff. Once that happens, the compression forces from the springs 504 continue to press the heatsink downwards towards the processors 106 and 104, thereby insuring proper contact (for heat transfer) between the heat spreaders, the thermal interface material, and the processors.

There are numerous advantages associated with embodiments of the floating core heatsink assembly described herein. The main advantage of this design is that the heatsink assembly can be mounted on multiple processors and peripheral memory modules (e.g., in order to dissipate heat from all those components), and the processors and peripheral memory modules can all be different height dimensions and tolerances. The floating core heatsinks can also be used to cool the main processors (e.g., processors 104 and 106 on the PCB 100) while the frame may act as a heatsink for the memory modules (e.g., memory modules 108). The spring-loaded fasteners also push the floating core heatsinks up and away from the frame, which causes the floating core heatsinks and the frame to be thermally disconnected.

Furthermore, the side of the frame facing the PCB has short standoffs, which act as a stiffener for the PCB (when the frame is fastened to the PCB) and prevents a bowing effect in the PCB under loading. In addition, the floating core heatsink assembly is usable with lid-less packages. The latest trend in electronic cooling is to remove the lid from integrated circuit (IC) packages to reduce the resistance of the thermal solution. To prevent excessive force exerted directly to the die, this assembly offers a very precise compression control attachment between main processor and the mating heatsink. In particular, the spring-loaded fasteners ensures an even force distribution exerted on the die. Furthermore, selection of different springs with different spring rates makes it possible to apply a variety of compression forces between heatsink and die. Finally, the individual floating core heatsinks are upgradable. Depending on needs, the floating core heatsink can have be an extrusion heatsink, an aluminum or copper stacked-fin heatsink, or a heatsink with vapor chamber base and aluminum or copper fins, or a heatsink incorporating heat pipes.

Terminology

The terms “approximately”, “about”, and “substantially” as used herein represent an amount close to the stated amount that still performs a desired function or achieves a desired result. For example, the terms “approximately”, “about”, and “substantially” may refer to an amount that is within less than 10% of, within less than 5% of, within less than 1% of, within less than 0.1% of, and within less than 0.01% of the stated amount.

Although this invention has been disclosed in the context of certain preferred embodiments and examples, it will be understood by those skilled in the art that the present invention extends beyond the specifically disclosed embodiments to other alternative embodiments and/or uses of the invention and obvious modifications and equivalents thereof. In addition, while a number of variations of the invention have been shown and described in detail, other modifications, which are within the scope of this invention, will be readily apparent to those of skill in the art based upon this disclosure. It is also contemplated that various combinations or sub-combinations of the specific features and aspects of the embodiments may be made and still fall within the scope of the invention. Accordingly, it should be understood that various features and aspects of the disclosed embodiments can be combined with or substituted for one another in order to form varying modes of the disclosed invention. Thus, it is intended that the scope of the present invention herein disclosed should not be limited by the particular disclosed embodiments described above.

Similarly, this method of disclosure is not to be interpreted as reflecting an intention that any claim require more features than are expressly recited in that claim. Rather, inventive aspects may lie in a combination of fewer than all features of any single foregoing disclosed embodiment. Thus, the claims following the Detailed Description are hereby expressly incorporated into this Detailed Description, with each claim standing on its own as a separate embodiment.

1. A floating core heatsink assembly comprising:
a frame adapted to be fastened to a circuit board, the frame comprising a first aperture and a first set of standoff posts on a top side of the frame;
a first floating core heatsink adapted to fit within the first aperture of the frame and to be fastened to the frame, wherein the first floating core heatsink comprises a set of apertures each configured to guide and receive insertion of a standoff post from the first set of standoff posts when the first floating core heatsink is fastened to the frame;
wherein the frame is configured to thermally couple with a first component on a circuit board when the frame is fastened to the circuit board, and wherein the first aperture is positioned over a second component on the circuit board when the frame is fastened to the circuit board,
wherein the frame stiffens the circuit board without a backing plate when the frame is fastened to the circuit board, and
wherein the first floating core heatsink is not thermally coupled to the frame when the first floating core heatsink is coupled with the second component.

2. The floating core heatsink assembly of claim 1, wherein the frame further comprises a second aperture, wherein the second aperture is positioned over a third component on the circuit board when the frame is fastened to the circuit board, wherein the floating core heatsink assembly further comprises a second floating core heatsink adapted to fit within the second aperture of the frame and to be fastened to the frame, and wherein the second floating core heatsink is not thermally coupled to the frame when the second floating core heatsink is coupled with the third component.

3. The floating core heatsink assembly of claim 1, wherein the frame comprises a layer of thermal interface material (TIM) on a side of the frame, the layer of thermal interface material configured to interface with the first component when the frame is fastened to the circuit board.

4. The floating core heatsink assembly of claim 1, wherein the first floating core heatsink comprises a set of cooling fins on a first side of the first floating core heatsink.

5. The floating core heatsink assembly of claim 4, wherein the first floating core heatsink comprises at least one heat pipe coupled with a second side of the first floating core heatsink.

6. The floating core heatsink assembly of claim 4, wherein the first floating core heatsink comprises a vapor chamber coupled with a second side of the first floating core heatsink.

7. The floating core heatsink assembly of claim 1, wherein the first floating core heatsink is fastened to the frame through at least one fastener that applies a spring force on the first floating core heatsink.

8. The floating core heatsink assembly of claim 7, wherein the spring force is adjustable.

9. The floating core heatsink assembly of claim 7, wherein the at least one fastener comprises:
a screw adapted to pass through an aperture of a standoff post of the first set of standoff posts located on the first side frame; and
a spring between a head of the screw and the first floating core heatsink.

10. The floating core heatsink assembly of claim 2, wherein the first component is a memory module, the second component is a processor, and the third component is a processor.

11. The floating core heatsink assembly of claim 2, wherein one or more of the first component, the second component, and the third component are of different heights.

12. The floating core heatsink assembly of claim 2, wherein the second floating core heatsink comprises a set of cooling fins on a first side of the second floating core heatsink

13. The floating core heatsink assembly of claim 2, wherein the second floating core heatsink comprises at least one heat pipe coupled with a second side of the second floating core heatsink.

14. The floating core heatsink assembly of claim 2, wherein the second floating core heatsink comprises a vapor chamber coupled with a second side of the first floating core heatsink.

15. The floating core heatsink assembly of claim 2, wherein the frame further comprises a third aperture, wherein the third aperture is positioned over a fourth component on the circuit board when the frame is fastened to the circuit board, wherein the floating core heatsink assembly further comprises a third floating core heatsink adapted to fit within the third aperture of the frame and to be fastened to the frame, and wherein the third floating core heatsink is not thermally coupled to the frame when the third floating core heatsink coupled with the fourth component.

16. The floating core heatsink assembly of claim 15, wherein the frame comprises a set of cooling fins disposed on a top side of the frame.

17. The floating core heatsink assembly of claim 3, wherein the frame further comprises a set of short standoffs on a bottom side of the frame.

18. The floating core heatsink assembly of claim 17, wherein the set of short of short standoffs are configured to provide a spacing between the frame and the circuit board when the frame is fastened to the circuit board.

19. The floating core heatsink assembly of claim 18, wherein the spacing fits the layer of thermal interface material interfaced with the first component when the frame is fastened to the circuit board.

20. The floating core heatsink assembly of claim 7, wherein the spring force is between the first floating core heatsink and the second component and causes the first floating core heatsink to be pushed away from the frame when the first floating core heatsink is fastened to the frame.
